(19) United States
(12) Patent Application Publication
(10) Pub. No.: US 2023/0134596 A1
(43) Pub. Date: May 4, 2023

(54) METAL STACK TO IMPROVE STACK THERMAL STABILITY

(71) Applicant: Texas Instruments Incorporated, Dallas, TX (US)

(72) Inventors: Fuchao Wang, Plano, TX (US); James Klawinsky, Murphy, TX (US); Albert M Estevez, Richardson, TX (US); Billy A Wofford, Sunnyvale, TX (US)

(21) Appl. No.: 17/514,039

(22) Filed: Oct. 29, 2021

(51) Int. Cl. H01L 21/768; H01L 21/285; H01L 23/532; C23C 14/06

(52) U.S. Cl. CPC H01L 21/76841; H01L 21/28568; H01L 23/53223; C23C 14/0641; H01L 21/76885

(57) ABSTRACT

A method of fabricating an integrated circuit includes forming a titanium nitride layer over a semiconductor substrate in a process chamber and forming a poisoned titanium layer on the titanium nitride layer in the process chamber. Forming the titanium nitride layer includes sputtering titanium from a titanium sputter target using a first nitrogen flow. Forming the poisoned titanium layer includes sputtering titanium from the titanium sputter target using a lower second nitrogen flow. The method also forms an aluminum layer on the poisoned titanium layer.

### BACKGROUND

Processes such as sintering at high temperatures during back end of line (BEOL) processing may stress the metallization stack for an integrated circuit (IC) chip formed in a semiconductor wafer and cause defects such as voids in metallization layers and/or cracks in the inter-level dielectric (ILD). When these defects cause a large number of chips to be discarded, there is a need to modify the existing metallization stack.

### SUMMARY

Various disclosed methods and devices of the present disclosure may be beneficially applied to integrated circuits that implement interconnections between electronic devices using heterogenous metal stacks. While such embodiments may be expected to reduce defects, e.g. after thermal cycling, no particular result is a requirement unless explicitly recited in a particular claim.

A metal stack includes successive layers of purified titanium (Ti), titanium nitride (TiN), and poisoned Ti under a layer of aluminum (Al), all three of which can be deposited in a single process chamber. Overlying the layer of Al are successive layers of poisoned Ti and TiN, which are also deposited in a single process chamber. The disclosed metal stack may provide one or both of improved resistance to voids and cracks and a tunable <111> Al crystalline structure.

In one aspect, an implementation of a method of fabricating an integrated circuit is disclosed. The method includes forming a titanium nitride layer over a semiconductor substrate in a process chamber and forming a poisoned titanium layer on the titanium nitride layer in the process chamber. Forming the titanium nitride layer includes sputtering titanium from a titanium sputter target using a first nitrogen flow and forming the poisoned titanium layer includes sputtering titanium from the titanium sputter target using a lower second nitrogen flow. The method also forms an aluminum layer on the poisoned titanium layer.

In another aspect, an implementation of an integrated circuit is disclosed. The integrated circuit includes a substantially pure Ti layer over a dielectric layer and a semiconductor substrate; a TiN layer over the substantially pure Ti layer, a poisoned Ti layer on the TiN layer; and an aluminum (Al) layer on the poisoned Ti layer.

In yet another aspect, an implementation of a method of forming an integrated circuit is disclosed. The method includes forming a dielectric layer over a semiconductor substrate and forming a first TiN layer over the dielectric layer in a first process chamber. Forming the first TiN layer uses a first Ti sputter target and the first TiN layer has an atomic concentration of Ti within a range from 45 at. % to 55 at. %. The method forms a first poisoned Ti layer that includes Ti and N directly on the first TiN layer; the first poisoned Ti layer has a higher concentration of N at a first side touching the first TiN layer and a lower concentration of N at a second side opposite the first side. The method continues with forming an Al layer on the first poisoned Ti layer. The method also forms a second poisoned Ti layer that includes Ti and N directly on the Al layer in a second process chamber using a second Ti sputter target. The second poisoned Ti layer has a higher concentration of N at a third side touching the Al layer and a lower concentration of N at a fourth side opposite the third side. The method continues by forming a second TiN layer directly on the second poisoned Ti layer in the second process chamber using the second Ti sputter target. The second TiN layer has an atomic concentration of Ti within a range from 45 at. % to 55 at. %.

### BRIEF DESCRIPTION OF THE DRAWINGS

Implementations of the present disclosure are illustrated by way of example, and not by way of limitation, in the figures of the accompanying drawings in which like references indicate similar elements. It should be noted that different references to “an” or “one” implementation in this disclosure are not necessarily to the same implementation, and such references may mean at least one. Further, when a particular feature, structure, or characteristic is described in connection with an implementation, it is submitted that it is within the knowledge of one skilled in the art to effect such feature, structure, or characteristic in connection with other implementations whether or not explicitly described. As used herein, the term “couple” or “couples” is intended to mean either an indirect or direct electrical connection unless qualified as in “communicably coupled” which may include wireless connections. Thus, if a first device couples to a second device, that connection may be through a direct electrical connection, or through an indirect electrical connection via other devices and connections. In addition, relationships such as “over”, “under”, “top”, etc. refer to the orientation as seen in the accompanying drawings.

The accompanying drawings are incorporated into and form a part of the specification to illustrate one or more exemplary implementations of the present disclosure. Various advantages and features of the disclosure will be understood from the following Detailed Description taken in connection with the appended claims and with reference to the attached drawing figures in which:

FIG. 1 depicts an example of a metal stack according to an implementation of the disclosure;

FIGS. 1A and 1B illustrate x-ray diffraction curves respectively according to two implementations of the disclosure in which different thicknesses of a poisoned Ti layer under the aluminum layer are used;

FIG. 1C depicts a graph 100C that plots the thickness of the first poisoned Ti layer 106 of FIG. 1 as a function of the FWHM in degrees of the resulting metal stack;

FIG. 1D depicts a portion of an IC chip in which the disclosed metal stack can be used according to an implementation of the disclosure;

FIG. 2 depicts a method of fabricating a metal stack for an IC chip according to an implementation of the disclosure;

FIG. 3A depicts the number of process chambers used to provide the metal stack of FIG. 4;

FIG. 3B depicts the number of process chambers used to provide the metal stack of FIG. 1 according to an implementation of the disclosure;

FIG. 4 depicts a metal stack according to the prior art;

FIG. 4A depicts the x-ray diffraction curve of the metal stack of FIG. 4;

FIG. 5 depicts a cross-section of multiple metal stacks using the metal stacks of FIG. 4 in which voids and cracks have occurred;

FIG. 6 depicts an additional metal stack according to the prior art; and

FIGS. 6A and 6B depict the x-ray diffraction curves respectively of the metal stack of FIG. 6 in which two different thickness of poisoned Ti are used.

### DETAILED DESCRIPTION

Specific implementations will now be described in detail with reference to the accompanying figures. In the following detailed description of implementations of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

In IC chip fabrication, a front-end-of-line (FEOL) process flow forms individual devices such as transistors, resistors, capacitors, etc. This is followed by a BEOL process flow that includes interconnecting the individual devices to form circuits using one or more metallization layers connected to the devices and to other metallization layers through vertical vias, all of which are formed in dielectric layers. Commonly, the metallization layers are largely made up of either aluminum or copper, although to improve the properties of the metallization layers such as flexibility and electromigration, one or more layers of metals and metal alloys, referred to as a metal stack, are typically used. The BEOL may include multiple iterations of the deposition of dielectric layers and the deposition and patterning of metallization layers. Once all metallization layers are completed, a final passivation layer and contact structures to the external world can be formed.

Several different forms of titanium are referenced in the present application, all of them using a Ti target and physical vapor deposition (PVD), sometimes referred to as sputtering. To achieve a “pure” Ti layer, a separate process chamber is reserved for Ti deposition, with no other processes taking place in the same process chamber, so that no contamination can occur. As used herein, a “poisoned” Ti layer refers to a titanium layer formed using a target that is initially contaminated with nitrogen or “poisoned”. The poisoned Ti layer may have a concentration of nitrogen that ranges between 5 at. % and 40 at. % and includes at least a portion that has a nitrogen concentration in a range between 3 at. % and 10 at. %. As the deposition continues, nitrided Ti from the target is removed as more the nitrogen-contaminated Ti is deposited, thereby purifying the Ti target. The amount of nitrogen in the poisoned Ti layer therefore decreases during the deposition, which may result in a detectable nitrogen concentration gradient in the poisoned Ti layer. The thickness of the deposited poisoned Ti layer will determine how purified the Ti target becomes. As used herein, a “purified” Ti layer is a Ti layer that is deposited using a Ti target that has been purified by sputtering the poisoned Ti from the target. A purified Ti layer is deposited in the same process chamber as a TiN layer, which is in contrast to the pure Ti layer described above. It is noted that while a pure Ti layer will typically contain only a trace concentration of nitrogen, a purified Ti layer may contain a greater concentration of nitrogen, e.g. up to a few ppm. Both a pure Ti layer and a purified Ti layer may be regarded as being substantially pure. As used herein, a “substantially pure” Ti layer and similar terminology means that the Ti layer includes no more than about 1 at. % nitrogen.

When aluminum is used as the primary conductor in wiring structures, two problems that must be dealt with are rigidity, which causes cracks and voids in the wiring structures, and electromigration, which is a tendency of the aluminum to move into the surrounding dielectric layer over time as current flows through the wiring. The aluminum is sandwiched between layers of other materials to achieve at least two different goals: to lessen the rigidity of the metal stack and to influence the crystalline structure of the deposited aluminum, which provides the best electromigration response when the aluminum has an orientation of <111>.

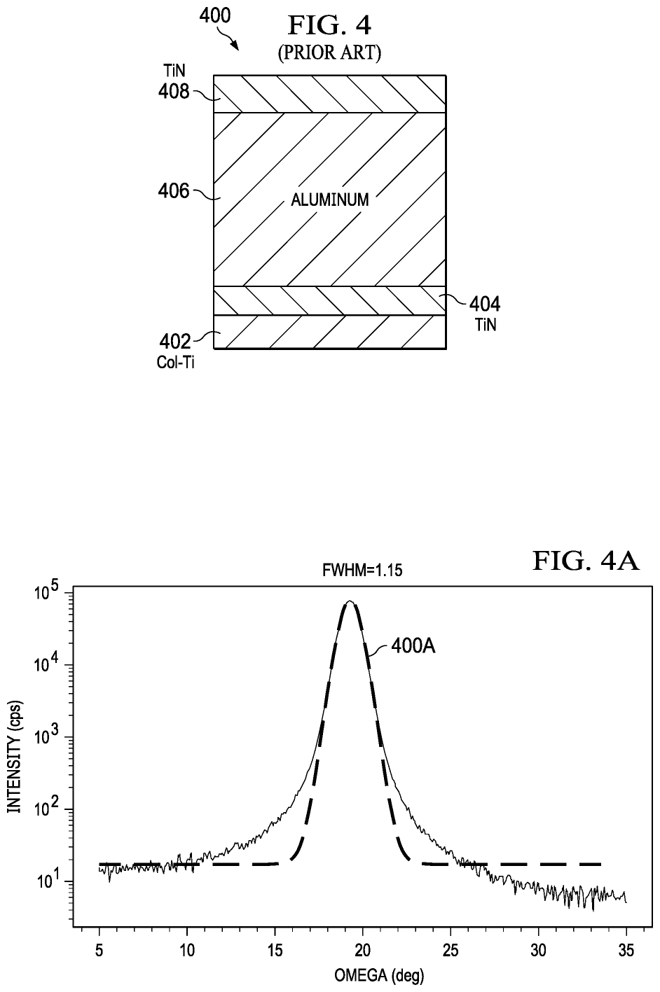

FIG. 4 depicts a metal stack 400 that was previously used in the analog device environment for which the present metal stack is designed. The metal stack 400 contains a collimated titanium (col-Ti) layer 402, which is pure titanium deposited using a collimator placed between the Ti target and the wafer on which the Ti is being deposited. A TiN layer 404 is deposited over the Col-Ti layer 402, with an aluminum layer 406 deposited over the TiN layer 404 and a final TiN layer 408 deposited over the Al layer 406. Although the metal stack 400 performs well and shows excellent electromigration performance, metal stack 400 is more rigid than desired and tends to form metal voids and cracks in ILD after thermal cycles such as the BEOL sintering, which is performed at 435° C., or HDP oxide (High Density Plasmas) deposition. These voids and cracks have resulted in a greater than one percent (1%) yield loss during automated visual inspection and resulting in a search for an improved metal stack.

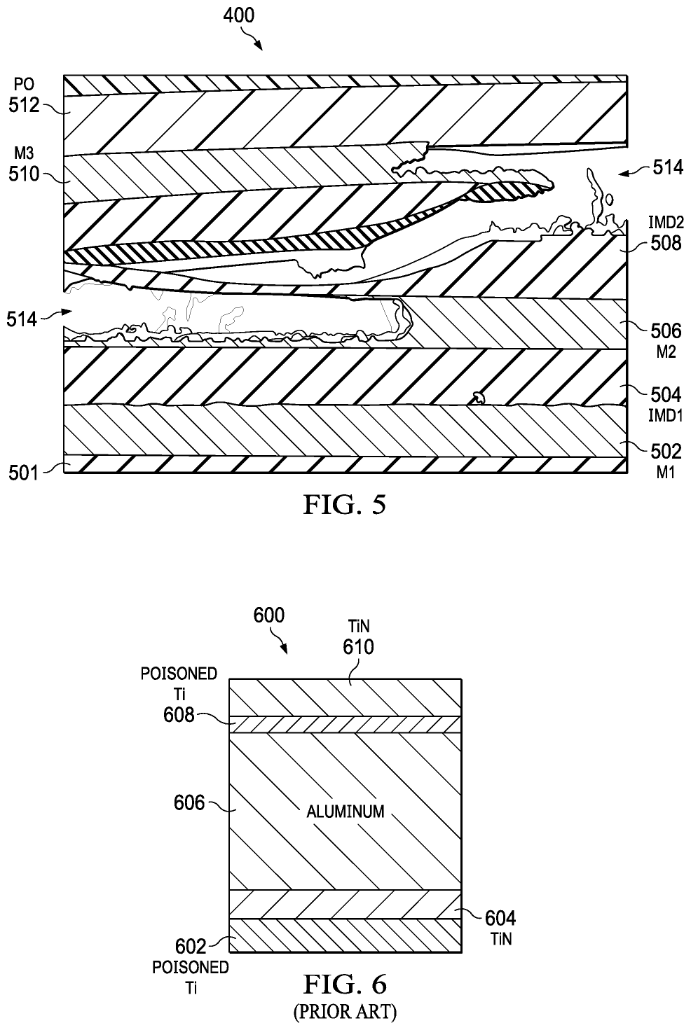

FIG. 4A depicts an x-ray diffraction (XRD) curve 400A used to characterize the metal stack 400. The XRD curve 400A shows a very sharp single peak having a full width half maximum (FWHM) of 1.15°, indicating that the metal stack 400 has a well oriented crystal structure, with a large grain size. The major problem with the metal stack 400 is the tendency to form voids and cracks after thermal cycling. This problem is illustrated in FIG. 5, which depicts a cross-section through a number of alternating metal layers and ILD layers. An IC chip 500 contains a pre-metal dielectric layer 501, which lies over a substrate (not explicitly shown). A metal-1 layer 502 is formed over the pre-metal dielectric layer 501 and is followed successively by an ILD-1 layer 504, a metal-2 layer 506, an ILD-2 layer 508, a metal-3 layer 510, and a protective overcoat 512. Although the metal-1 layer 502, the metal-2 layer 506, and the metal-3 layer 510 were originally well formed, the cross-section has been taken after a sintering process and displays large cracks and voids 514, making the associated chip unusable. As a result, more than one percent of the chips on a wafer were necessarily discarded after visual inspection. This was considered to be unacceptable and a search for a more robust replacement was sought.

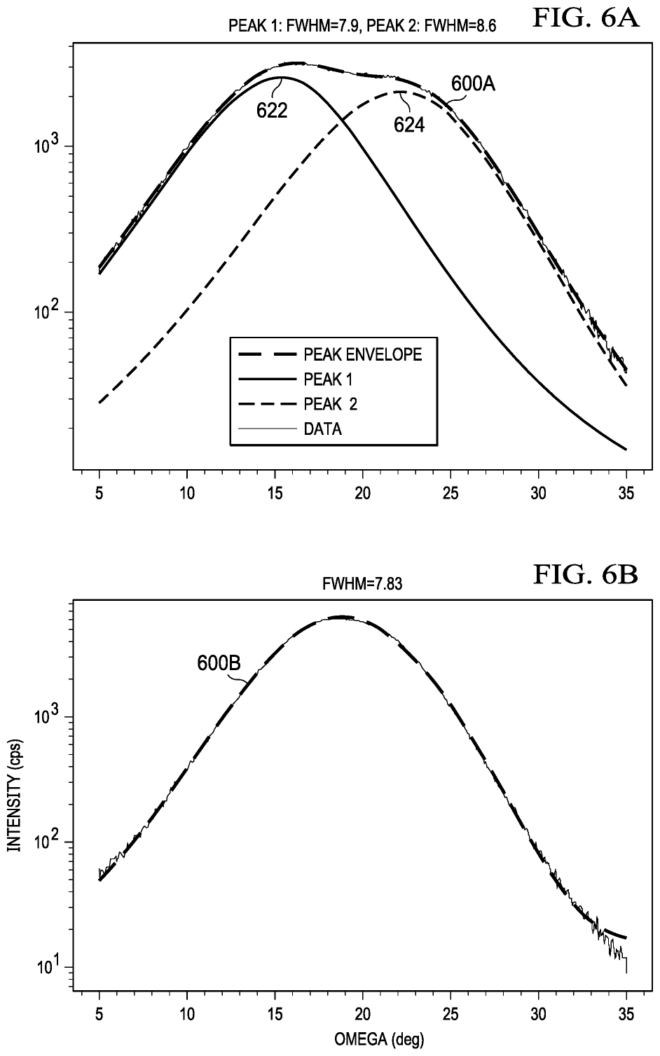

FIG. 6 depicts another metal stack 600 that has been shown to provide greater robustness against metal void formation than the metal stack 400. The metal stack 600 begins with a poisoned Ti layer 602. A TiN layer 604 lies over the poisoned Ti layer 602 and an aluminum layer 606 lies over the TiN layer 604. Another poisoned Ti layer 608 lies over the aluminum layer 606 and an additional TiN layer 610 lies over the poisoned Ti layer 608.

FIG. 6A depicts an XRD curve 600A for a first version of the metal stack 600 in which the poisoned Ti layer 602 is about 200 Å thick, the TiN layer 604 is about 425 Å thick, the Al layer 606 is about 5350 Å thick, the poisoned Ti layer 608 is about 150 Å thick, and the TiN layer 610 is about 500 Å thick. The data points in the XRD curve 600A form a broad envelope. When peaks are fitted to the XRD curve 600A, two peaks are found; a first peak 622 having an FWHM of 7.9° and a second peak 624 having an FWHM of 8.6°. These two broad peaks each indicate a degraded crystal structure, which is not optimal for electromigration performance.

FIG. 6B depicts an XRD curve 600B for a second version of the metal stack 600 in which the poisoned Ti layer 602 is increased to about 300 Å thick, while the TiN layer 604 remains about 425 Å thick, the Al layer 606 remains about 5350 Å thick, the poisoned Ti layer 608 remains about 150 Å thick, and the TiN layer 610 remains about 500 Å thick. With this change, the data points in the XRD curve 600B form a single peak, which is still quite broad with an FWHM of 7.83° and still not optimal for electromigration performance. Thus, the metal stack 600 would not be desirable as a replacement for the metal stack 400.

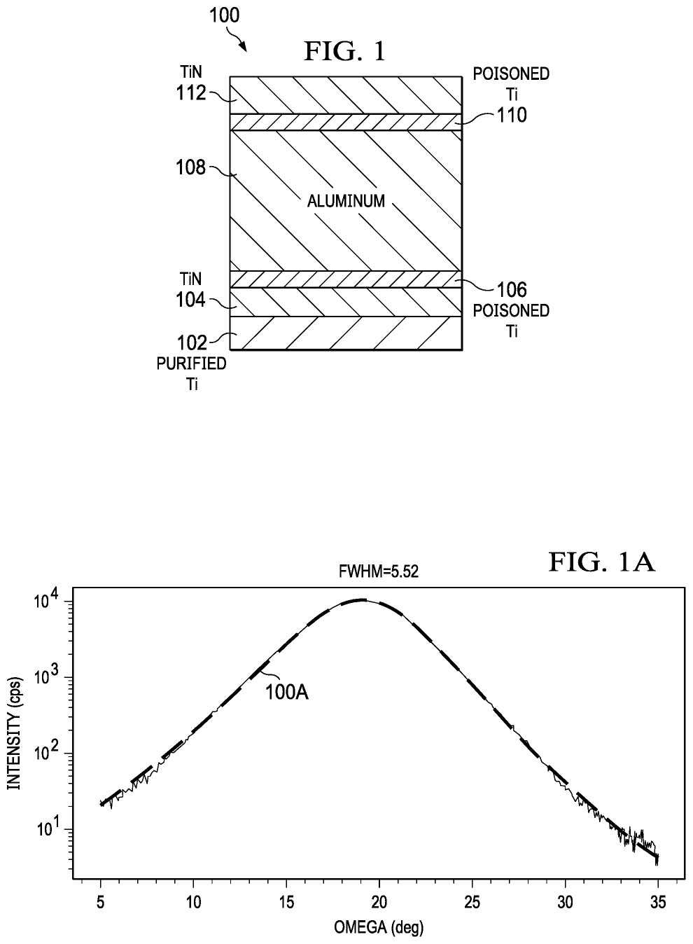

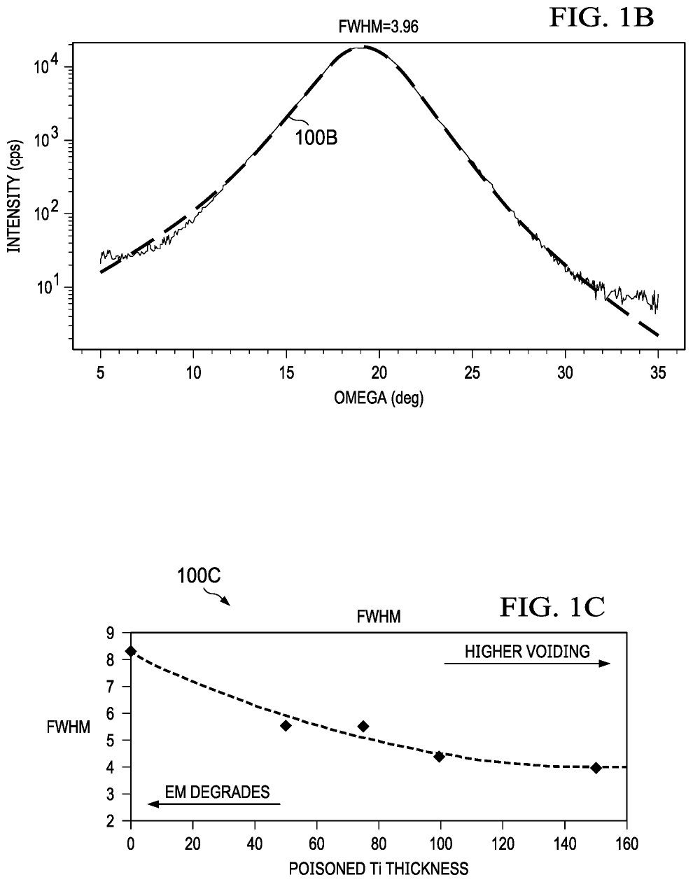

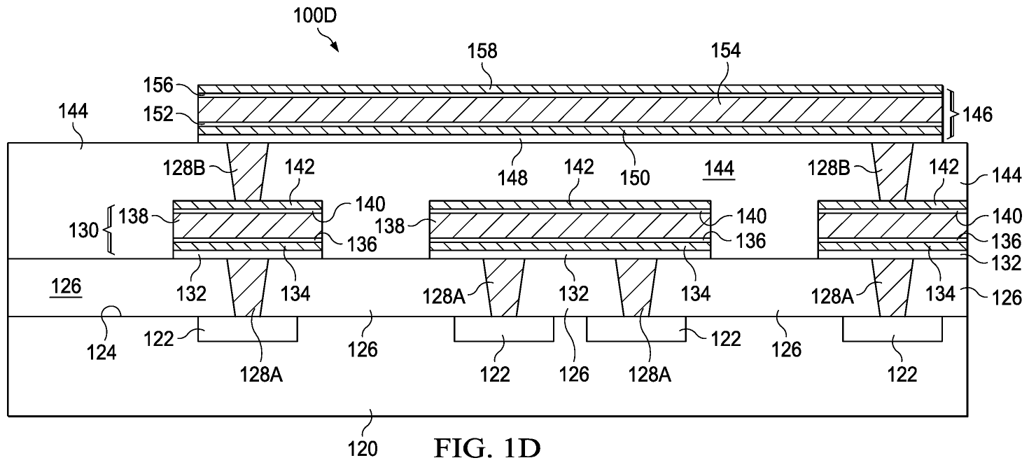

FIG. 1 depicts a metal stack 100 according to an implementation of the disclosure. The bottom portion of the metal stack 100 contains a purified Ti layer 102, which can also be described as a substantially pure Ti layer 102, deposited over a dielectric layer (not specifically shown), a first TiN layer 104 deposited over the purified Ti layer 102, and a first poisoned Ti layer 106 formed over the first TiN layer 104. Because this bottom portion of the metal stack uses a “purified” Ti rather than a “pure” Ti, these bottom three layers can be formed in a single process chamber, as will be discussed in greater detail below. An aluminum layer 108 is deposited over the first poisoned Ti layer 106, a second poisoned Ti layer 110 is deposited over the Al layer 108, and a second TiN layer 112 is deposited over the second poisoned Ti layer 110. While the aluminum requires a separate process chamber for deposition, the second poisoned Ti layer 110 and the second TiN layer 112 can both be deposited in the same process chamber. As noted previously, the first poisoned Ti layer 106 has been added directly under the Al layer 108 and, in combination with the purified Ti layer 102, may be used to modulate the orientation of the Al layer 108 and provide a desired crystalline structure. In the past, the use of a pure Ti layer at the bottom of similar stacks has been a key factor affecting the structure of the Al, but the need for a separate process chamber increases the cost of production. In addition to modulating the orientation of the Al layer 108, the deposition of the first poisoned Ti layer 106 cleans the Ti target to provide the purified Ti layer 102 for the next wafer, providing a significant cost savings.

Two different thicknesses of the first poisoned Ti layer 106 have been tested, with both thicknesses demonstrating a single peak with respective low FWHM. Additionally, by altering the thickness of the first poisoned Ti layer 106, the FWHM can be tuned as needed. Each of the two implementations of the metal stack 100 include about 200 Å of the purified Ti layer 102, about 425 Å of the first TiN layer 104, about 5350 Å of the Al layer 108, about 150 Å of the second poisoned Ti layer 110, and about 500 Å of the second TiN layer 112. Notably, the thickness of the Al layer can be variable, but is generally greater than about 5,000 Å.

Looking at FIG. 1A, the implementation of the metal stack 100 used to create XRD curve 100A includes about 50 Å of the first poisoned Ti layer 106 and the XRD curve 100A has an FWHM of 5.52°. In FIG. 1B, the implementation of the metal stack 100 includes 150 Å of the first poisoned Ti layer 106 and XRD curve 100B has an FWHM of 3.96°. Increasing the thickness of the first poisoned Ti layer 106 increases the time during which nitrogen present on the Ti target may be incorporated into the poisoned Ti layer and thus modulates the purity of the purified Ti layer 102 that will be deposited on the following wafer. The disclosed metal stack 100 resists voiding and has a tunable Al texture that can be adjusted as desired to promote good electromigration capability.

FIG. 1C depicts a graph 100C that plots the thickness of the first poisoned Ti layer 106 against the corresponding FWHM for the metal stack 100. When no poisoned Ti layer is formed directly under the Al layer, e.g., in the example of FIG. 6, the FWHM is quite high, e.g., greater than eight degrees. As the thickness of the poisoned Ti layer increases from about 40 Å to about 150 Å, the FWHM drops into a range between about 4-6°. In the context of thickness, the term “about” means ±10%. As noted in graph 100C, too low an FWHM can lead to higher voiding, while too high an FWHM can lead to degradation of the electromigration tendencies of the aluminum. An FWHM in the range of 5-6° may provide the best overall results, but has not been verified at this point because testing for electromigration can take years.

FIG. 1D depicts a portion of a wafer 100D that utilizes a metal stack according to an implementation of the disclosure. The wafer 100D includes a semiconductor substrate 120 having a top surface 124 and a number of electronic devices 122 formed at the top surface. A pre-metal dielectric layer 126 is over the substrate and contains a first set of vias 128A that extend through the pre-metal dielectric layer 126 to contact respective ones of the electronic devices 122. Portions of a first metal stack 130 that has been deposited and patterned are shown. The first metal stack 130 includes a first purified Ti layer 132, a first TiN layer 134, and a first poisoned Ti layer 136 below a first Al layer 138. Over the first Al layer 138 is a second poisoned Ti layer 140 and a second TiN layer 142.

A first inter-level dielectric layer 144 lies over the first metal stack 130 and over portions of the pre-metal dielectric layer 126 and contains a second set of vias 128B that extend through the first inter-level dielectric layer 144 to contact parts of the first metal stack 130. A second metal stack 146 has been deposited and patterned. The second metal stack 146 includes a second purified Ti layer 148, a third TiN layer 150, and a third poisoned Ti layer 152 below a second Al layer 154. Over the second Al layer 154 is a fourth poisoned Ti layer 156 and a fourth TiN layer 158.

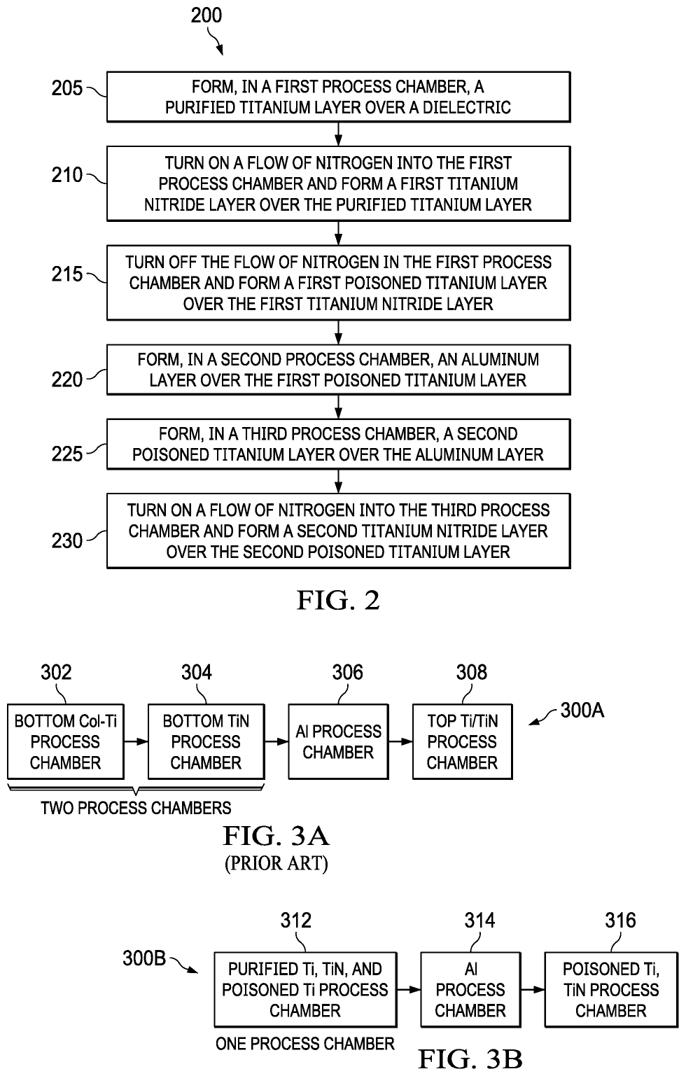

Turning to FIG. 2, a method 200 of fabricating an IC chip on a semiconductor wafer, the IC chip containing a metal stack according to the disclosure. When the method 200 begins, a wafer containing a semiconductor substrate with a top surface on which semiconductor devices have been formed is provided. Additionally, a dielectric layer has been formed over the semiconductor substrate and desired contacts have been formed through the dielectric layer to contact the substrate or lower metal stacks. The dielectric layer can be a pre-metal dielectric layer, which is deposited over the substrate, or can be an inter-level dielectric, which is deposited over a lower metallization layer and a portion of an underlying dielectric layer. The semiconductor substrate is now ready for the disclosed metal stack to be formed.

The method 200 begins at 205 with forming, in a first process chamber, a purified titanium layer, e.g. the purified Ti layer 102, over the dielectric layer. In one implementation, the first process chamber is a PVD chamber having a pressure less than about 10 mTorr (1.3 Pa); the PVD chamber contains a Ti target and is coupled to provide a flow of argon and a flow of nitrogen. The flow of argon is continuous, with a flow rate that varies at each stage of the process, while the flow of nitrogen is provided only for the deposition of TiN. As the wafer is introduced into the first process chamber, the flow of argon is set to about 100 standard cubic centimeters per minute (sccm) for a few seconds, e.g., for about 5 seconds. Deposition of the purified titanium is at a power of about 1 kW DC, for a duration “X” that is determined by the desired thickness of the purified titanium layer. During the deposition of the purified Ti layer, the flow of argon is reduced to about 45 sccm. For a few seconds after the deposition of the purified Ti layer, e.g., for about 5 seconds, the DC power is turned off and the flow of argon is increased to about 60 sccm.

The method 200 continues with 210, turning on a flow of nitrogen into the first process chamber and forming a first titanium nitride layer, e.g. the TiN layer 104, over the purified titanium layer, e.g. the a purified Ti layer 102. In one implementation, the nitrogen is turned on at the same time that the flow of argon is increased. The flow of nitrogen may be set to about 55 sccm. After the gases are adjusted, DC power in the first process chamber is set to about 1 kW. The DC power is increased to about 6500 Watts after a delay, e.g. about 3 s, and TiN deposition is started. During the deposition of the TiN, the flow of argon is decreased to about 45 sccm while the flow of nitrogen is maintained at about 55 sccm. The TiN is deposited for a duration “Y” that is determined by the desired thickness of the TiN layer. While the concentration of nitrogen in a stoichiometric TiN layer is 50 at. %, the nitrogen concentration in the first TiN layer 104 may differ somewhat from 50 at. %, e.g. may range from about 45 at. % to about 55 at. %.

The method 200 continues at 215 with turning off the flow of nitrogen in the first process chamber and forming a first poisoned titanium layer over the first titanium nitride layer. In some implementations the first process chamber pressure is not brought to atmospheric pressure between forming the first titanium nitride layer and forming the first poisoned titanium layer, e.g. the vacuum in the first process chamber is not broken. In one implementation, when the nitrogen flow is turned off, the flow of argon is increased to 100 sccm for a period of about 5 seconds. The flow of argon is then reduced to about 45 sccm and the poisoned Ti deposition is performed at a DC power of about 1 kW. The poisoned Ti is deposited for a duration “Z” that will determine the thickness of the poisoned Ti layer. At the end of the duration Z, the wafer will be automatically removed from the first process chamber and a next wafer will be introduced to begin deposition of a new purified Ti layer using the Ti target, which has been purified by the deposition of the poisoned Ti layer.

The method 200 next proceeds at 220 to forming, in a second process chamber, an Al layer over the first poisoned titanium layer. In one embodiment, the deposition of the aluminum layer can occur in a PVD chamber under an Ar plasma and at a temperature below 350° C. A process pressure of less than 10 mTorr (1.3 Pa) may be used at a DC power of between about 4-60 kW.

The method 200 next continues at 225 with forming, in a third process chamber, a second poisoned Ti layer over the Al layer and finishes at 230 with turning on a flow of nitrogen into the third process chamber and forming a second titanium nitride layer over the second poisoned titanium layer. After the deposition of the second titanium nitride layer, the flow of the nitrogen into the third process chamber is turned off and the semiconductor wafer is again automatically removed from the third process chamber and another semiconductor wafer is introduced into the third process chamber. The third process chamber can be similar to the first process chamber in that the third process chamber contains a titanium target and is coupled to receive a flow of argon and a flow of nitrogen. In one implementation, the process for deposition of the second poisoned titanium layer is similar to the deposition of the first poisoned titanium layer and the process for deposition of the second titanium nitride layer is similar to the deposition of the first titanium nitride layer, with adjustments for the lack of a purified titanium layer.

The BEOL processing of the wafer will continue after the deposition of the second titanium nitride layer with, for example, patterning and etching of the metal stack to form a desired metallization layer, followed by the formation of additional dielectric layers and metallization layers and of a protective overcoat over the surface of the wafer, but these are beyond the scope of this disclosure and are not discussed in greater depth.

FIG. 3A and FIG. 3B illustrate one advantage of the disclosed method, e.g., that the process can eliminate one process chamber for processing the metal stack as opposed to the current metal stack. FIG. 3A graphically depicts the process flow 300A used to deposit the metal stack shown in FIG. 4. A bottom col-Ti deposition chamber 302 is dedicated to the deposition of titanium using a collimator. A bottom TiN deposition chamber 304 is also used to deposit a single layer, as is aluminum deposition chamber 306. Only a top Ti/TiN deposition chamber 308 deposited two layers, so that the five layers in metal stack 400 require four process chambers. FIG. 3B graphically depicts a process flow 300B used to deposit the metal stack 100. In the process 300B, a first process chamber 312 is used to deposit all three of the bottom layers of purified Ti, TiN, and poisoned Ti. The aluminum layer is still deposited in a separate, second process chamber 314, while the top two layers of poisoned Ti and TiN are deposited in a third process chamber 316. Thus, while the metal stack 100 contains one more layer than the metal stack 400, one less process chamber is necessary for the deposition of the metal stack.

Applicants have disclosed a metal stack for an IC chip that includes successive layers of purified Ti, TiN, poisoned Ti, aluminum, poisoned Ti, and TiN. The disclosed metal stack resists the voids and cracks that have caused wastage in the previous metal stack, while maintaining an Al crystalline structure that promotes lower levels of electromigration and that is tunable by adjusting the thickness of the first poisoned Ti layer. The processing of the metal stack may be improved by eliminating the need for a separate process chamber in which to deposit a pure Ti layer.

Although various implementations have been shown and described in detail, the claims are not limited to any particular implementation or example. None of the above Detailed Description should be read as implying that any particular component, element, step, act, or function is essential such that it must be included in the scope of the claims. Reference to an element in the singular is not intended to mean “one and only one” unless explicitly so stated, but rather “one or more.” All structural and functional equivalents to the elements of the above-described implementations that are known to those of ordinary skill in the art are expressly incorporated herein by reference and are intended to be encompassed by the present claims. Accordingly, those skilled in the art will recognize that the exemplary implementations described herein can be practiced with various modifications and alterations within the spirit and scope of the claims appended below.

What is claimed is:

1. A method of fabricating an integrated circuit, comprising:
forming a titanium nitride layer over a semiconductor substrate, including sputtering titanium from a titanium sputter target in a process chamber including a first nitrogen flow;
forming a poisoned titanium layer on the titanium nitride layer, including sputtering titanium from the titanium sputter target in the process chamber including a lower second nitrogen flow; and
forming an aluminum layer on the poisoned titanium layer.

2. The method as recited in claim 1, wherein the titanium nitride layer is formed on a substantially pure titanium layer.

3. The method as recited in claim 2, wherein the substantially pure titanium layer is formed using the titanium sputter target.

4. The method as recited in claim 1, wherein the titanium nitride layer is formed over a dielectric layer.

5. The method as recited in claim 1, wherein the poisoned titanium layer and the titanium nitride layer are formed in a same process chamber.

6. The method as recited in claim 1, wherein the second nitrogen flow is no nitrogen flow.

7. The method as recited in claim 1 further including:
forming a second poisoned titanium layer on the aluminum layer; and
forming a second titanium nitride layer over the second poisoned titanium layer.

8. The method as recited in claim 7, wherein the second poisoned titanium layer and the second titanium nitride layer are formed in a different second process chamber.

9. The method as recited in claim 7 in which the forming of the substantially pure titanium layer is performed using a flow of argon of about 100 sccm and a DC power of about 1 kW.

10. The method as recited in claim 1 in which the forming of the titanium nitride layer is performed using a flow of argon of about 45 sccm, a flow of nitrogen of about 55 sccm, and a DC power of about 6.5 kW.

11. The method as recited in claim 1 in which the forming of the poisoned titanium layer is performed using a flow of argon of about 45 sccm and a DC power of about 1 kW.

12. An integrated circuit, comprising:
a substantially pure titanium (Ti) layer over a dielectric layer and a semiconductor substrate;
a titanium nitride (TiN) layer over the substantially pure Ti layer;
a poisoned Ti layer on the TiN layer; and
an aluminum (Al) layer on the poisoned Ti layer.

13. The metal stack as recited in claim 12 including:
a second poisoned Ti layer on the Al layer; and
a second TiN layer on the second poisoned Ti layer.

14. The integrated circuit as recited in claim 12 in which the substantially pure Ti layer has a nitrogen concentration no greater than 1 at. %.

15. The integrated circuit as recited in claim 12 in which the poisoned Ti layer has a thickness in a range between about 40 Å and about 150 Å.

16. The integrated circuit as recited in claim 12 in which the substantially pure Ti layer is over an inter-level dielectric.

17. A method of forming an integrated circuit, comprising:
forming a dielectric layer over a semiconductor substrate;
forming a first TiN layer over the dielectric layer in a first process chamber using a first Ti sputter target, the first TiN layer having an atomic concentration of Ti within a range from 45 at. % to 55 at. %;
forming a first poisoned Ti layer comprising Ti and N directly on the first TiN layer, the first poisoned Ti layer having a higher concentration of N at a first side touching the first TiN layer and a lower concentration of N at a second side opposite the first side;
forming an Al layer on the first poisoned Ti layer;
forming a second poisoned Ti layer comprising Ti and N directly on the Al layer in a second process chamber using a second Ti sputter target, the second poisoned Ti layer having a higher concentration of N at a third side touching the Al layer and a lower concentration of N at a fourth side opposite the third side; and
forming a second TiN layer directly on the second poisoned Ti layer in the second process chamber using the second Ti sputter target, the second TiN layer having an atomic concentration of Ti within a range from 45 at. % to 55 at. %.

18. The method as recited in claim 17, further comprising patterning the Al layer to form an interconnection between first and second electronic devices formed between the dielectric layer and the semiconductor substrate.

19. The method as recited in claim 17, wherein the first TiN layer is formed using a first plasma power and a first process chamber pressure and the first poisoned Ti layer is formed using a different second plasma power and a different second process chamber pressure.

20. The method as recited in claim 19, further comprising forming a Ti layer over the dielectric layer in the first process chamber using the first Ti sputter target, the Ti layer having an atomic concentration of Ti equal to 99.9% or greater, and the first TiN layer formed directly on the Ti layer.
